(19) United States
(12) Patent Application Publication
(10) Pub. No.: US 2012/0068244 A1
(43) Pub. Date: Mar. 22, 2012

(54) SEMICONDUCTOR MEMORY DEVICE AND METHOD FOR MANUFACTURING SAME

(75) Inventor: Yoshiki KATO, Mie-ken (JP)

(73) Assignee: KABUSHIKI KAISHA TOSHIBA, Tokyo (JP)

(21) Appl. No.: 13/236,771

(22) Filed: Sep. 20, 2011

(30) Foreign Application Priority Data
Sep. 21, 2010 (JP) 2010-210848

(51) Int. Cl. H01L 29/788; H01L 21/266

(52) U.S. Cl. 257/315; 438/527; 257/E29.3; 257/E21.346

(57) ABSTRACT

According to an embodiment, a semiconductor memory device includes a plurality of multi-level memory cells provided on a major surface of a semiconductor substrate of a first conductivity type. A first semiconductor region of a second conductivity type is selectively provided in the surface of the semiconductor substrate between the multi-level memory cells. A second semiconductor region is provided deeper than the first semiconductor region and includes a first conductivity type impurity. A plurality of binary memory cells are provided on the major surface of the semiconductor substrate, and a third semiconductor region of the second conductivity type is selectively provided in the surface of the semiconductor substrate between the binary memory cells. Amount of the first conductivity type impurity compensating a second conductivity type impurity of the first semiconductor region is larger than that of the third semiconductor region.

### CROSS-REFERENCE TO RELATED APPLICATIONS

This application is based upon and claims the benefit of priority from Japanese Patent Application No. 2010-210848, filed on Sep. 21, 2010; the entire contents of which are incorporated herein by reference.

### FIELD

Embodiments are generally related to a semiconductor memory device and a method for manufacturing the same.

### BACKGROUND

With the development of miniaturization technologies used to manufacture semiconductor devices and the like, high capacity semiconductor memory devices have been realized. For instance, NAND flash memories are used in widespread applications as small, portable, and high capacity memory devices.

However, in a NAND flash memory, after repeating writing and erasure of data, memory cells are degraded and may fail to store data normally. With the scaling down of the design rule, endurance for writing and erasure (endurance characteristic) tends to decrease. Thus, there is demand for a high capacity semiconductor memory device with improved endurance characteristic.

### BRIEF DESCRIPTION OF THE DRAWINGS

FIGS. 1A and 1B are schematic views illustrating a semiconductor memory device according to an embodiment;

FIGS. 2A to 2C are schematic cross-sectional views illustrating a structure of the semiconductor memory device according to the embodiment;

FIGS. 3A and 3B are schematic diagrams showing a distribution of impurity doped in the semiconductor memory device according to the embodiment;

FIGS. 4A and 4B are schematic cross-sectional views illustrating a degradation of the semiconductor memory device according to the embodiment;

FIGS. 5A and 5B are schematic views illustrating a cross-sectional structure of a semiconductor memory device according to a variation of the embodiment;

FIGS. 6A and 6B are schematic diagrams illustrating a distribution of impurity doped in the semiconductor memory device according to the variation of the embodiment;

FIGS. 7A and 7B are schematic views illustrating a cross-sectional structure of a semiconductor memory device according to an alternative variation of the embodiment;

FIG. 8 is a graph showing endurance for writing and erasure of the semiconductor memory device according to the embodiment;

FIG. 9 is a schematic cross-sectional view illustrating a memory cell of the semiconductor memory devices according to the embodiment;

FIGS. 10A and 10B are schematic diagrams showing a threshold distribution of the memory cells of the semiconductor memory devices according to the embodiment.

### DETAILED DESCRIPTION

In general, according to an embodiment, a semiconductor memory device includes a plurality of multi-level memory cells provided on a major surface of a semiconductor substrate of a first conductivity type along a first direction parallel to the major surface. A first semiconductor region of a second conductivity type is selectively provided in the surface of the semiconductor substrate between the multi-level memory cells adjacent in the first direction. A second semiconductor region is provided deeper than the first semiconductor region from the major surface and includes a first conductivity type impurity. A plurality of binary memory cells are provided on the major surface of the semiconductor substrate along a second direction parallel to the major surface, and a third semiconductor region of the second conductivity type is selectively provided in the surface of the semiconductor substrate between the binary memory cells adjacent in the second direction. Amount of the first conductivity type impurity compensating a second conductivity type impurity of the first semiconductor region is larger than amount of the first conductivity type impurity compensating the second conductivity type impurity of the third semiconductor region.

Embodiments of the invention will now be described with reference to the drawings. In the following embodiments, like portions in the drawings are labeled with like reference numerals. The detailed description of the like portion is omitted as appropriate and the different portions are described. In the following description, the first conductivity type is p-type and the second conductivity type is n-type, and alternately the embodiments are also practicable, where the first conductivity type is n-type and the second conductivity type is p-type.

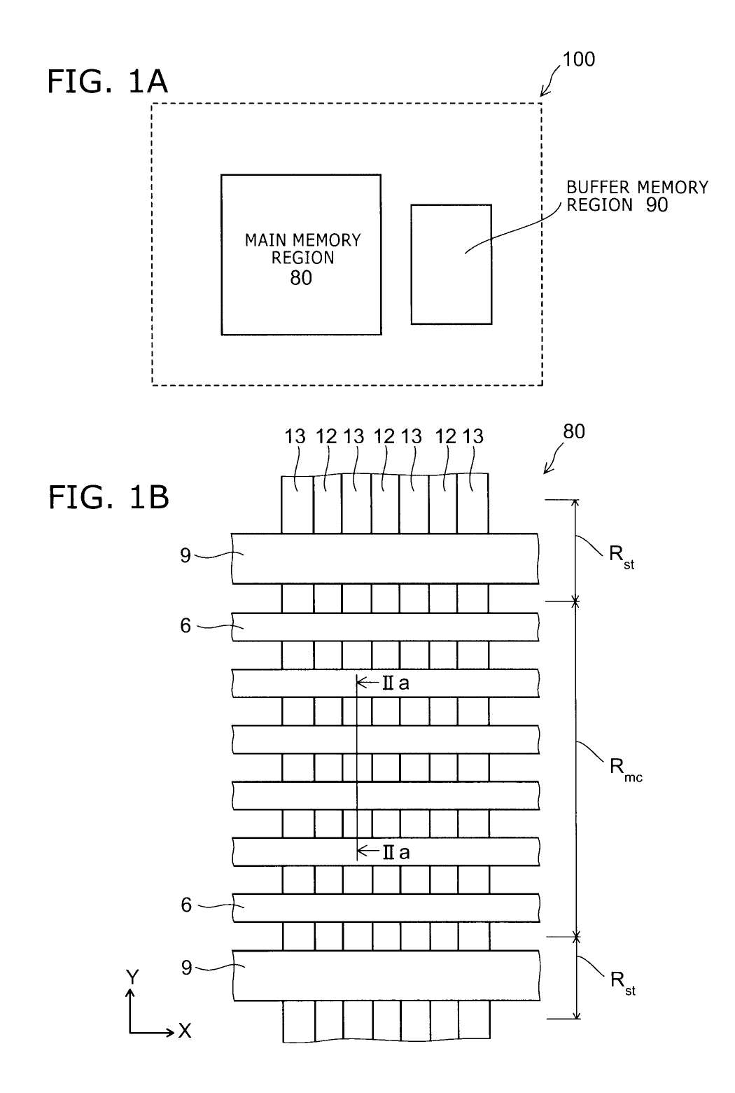

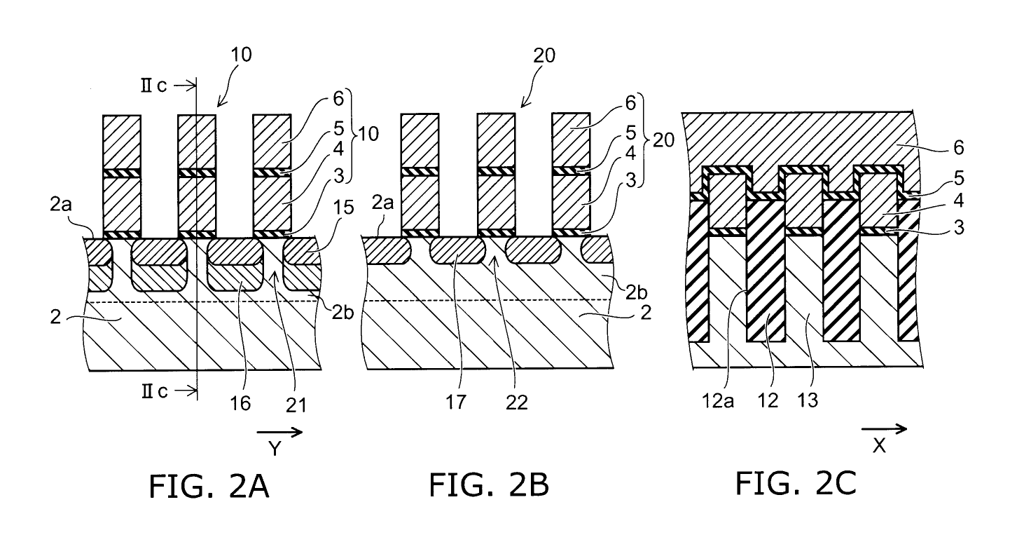

FIGS. 1A and 1B are schematic views showing a semiconductor memory device 100 according to an embodiment. The semiconductor memory device 100 is e.g. a NAND flash memory. As shown in FIG. 1A, the semiconductor memory device 100 includes a main memory region 80 and a buffer memory region 90. The main memory region 80 and the buffer memory region 90 are configured to include memory strings including a plurality of memory cells (see FIGS. 2A to 2C).

FIG. 1B is a schematic view showing the configuration of the main memory region. The main memory region 80 includes a memory cell region R_{mc} and select transistor regions Rₛₜ. The memory cell region R_{mc} is provided between two select transistor regions Rₛₜ. A plurality of memory strings 13 and a plurality of STIs (shallow trench isolations) 12 are alternately arranged through the memory cell region R_{mc} and the select transistor regions Rₛₜ. The STI 12 extends in the Y direction like the memory string 13 and isolates adjacent memory strings 13 from each other.

Furthermore, a plurality of control gate electrodes 6 and select gate electrodes 9 are provided across the memory strings 13 and the STIs 12 in the X direction. A memory cell is arranged at the intersection of the memory string 13 and the control gate electrode 6. A select transistor is arranged at the intersection of the memory string 13 and the select gate electrode 9.

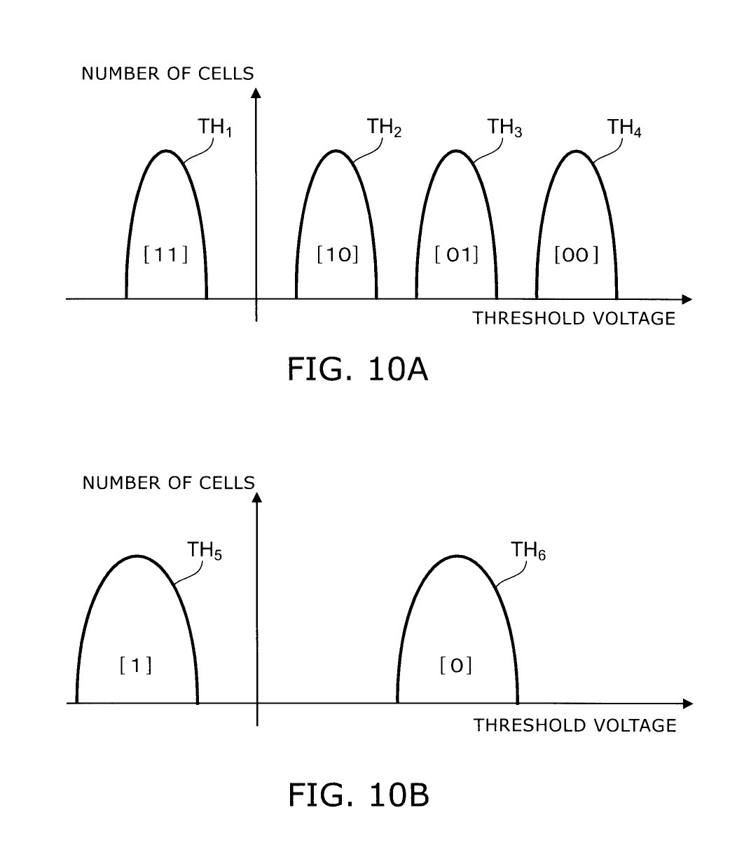

In the semiconductor memory device 100 according to the embodiment, the memory cell arranged in the main memory region 80 operates as a multi-level memory cell (multi-level cell, MLC). As shown in FIG. 10A, for instance, the MLC stores multi-level data corresponding to a plurality of threshold voltages. Hence, the memory capacity can be increased by arranging MLCs in the main memory region 80.

However, the MLC has the property of slow writing and reading speed. Thus, in order to alleviate the decrease of writing and reading speed in the main memory region 80 including MLCs, the semiconductor memory device 100 includes a buffer memory region 90. The buffer memory region 90 includes memory cells each of which operates as a binary memory cell (single level cell, SLC) that has faster writing and reading speed than the MLC. The buffer memory region 90 can also be configured as shown in FIG. 1B.

MLCs are arranged in the Y direction (a first direction), in which the memory string 13 extends in the main memory region 80 as shown in FIG. 1B. On the other hand, SLCs are arranged in a second direction that is also the extending direction of the memory string in the buffer memory region 90. The extending direction of the memory string 13 in the main memory region 80 may be identical to or different from the extending direction of the memory string in the buffer memory region 90.

FIGS. 2A to 2C are schematic views showing the structure of the semiconductor memory device 100. More specifically, FIG. 2A shows the structure of the IIa-IIa cross-section of the main memory region 80 shown in FIGS. 1A and 1B. FIG. 2B shows the cross-sectional structure of the portion corresponding to the IIa-IIa cross section in the buffer memory region 90. FIG. 2C shows the structure of the IIc-IIc cross-section shown in FIG. 2A.

As shown in FIG. 2A, in the main memory region 80, a plurality of MLCs 10 are provided on the major surface 2a of a p-type semiconductor substrate 2. The MLC 10 has a stacked structure including a gate insulating film 3, a floating gate 4, an interelectrode insulating film 5, and a control gate electrode 6 formed on the surface of the semiconductor substrate 2. A p-region 2b (fifth semiconductor region) for adjusting the threshold voltage of the MLC 10 is provided in the surface of the semiconductor substrate 2.

The MLCs 10 are arranged in the Y direction in which the memory string 13 extends parallel to the major surface 2a of the semiconductor substrate 2. A source and drain (source/drain) region 15 as an n-type first semiconductor region is provided in the surface of the semiconductor substrate 2 between the MLCs 10 adjacent in the Y direction.

Furthermore, a p⁻-region 16 as a second semiconductor region is provided below the source/drain region 15. The p⁻-region 16 includes p-type impurity selectively introduced from the surface of the source/drain region 15 and distributed in the depth direction of the semiconductor substrate 2.

As shown in FIG. 2C, the memory strings 13 adjacent in the X direction orthogonal to the Y direction are electrically isolated from each other by the STI 12. The STI 12 is formed from an insulating film such as a silicon oxide film (SiO₂ film) buried from the bottom portion of a trench 12a provided in the semiconductor substrate 2 up to the side surface of the floating gate 4. This reduces leakage current between the adjacent memory strings 13.

In contrast, in the Y direction, the p⁻-region 16 provided below the source/drain region 15 reduces leakage current between the channels 21 formed below the adjacent MLCs 10. The p⁻-region 16 is a so-called halo region, which reduces the short channel effect of the adjacent MLCs 10.

On the other hand, in the buffer memory region 90 shown in FIG. 2B, a plurality of SLCs 20 are provided on the major surface 2a of the semiconductor substrate 2. As shown in this figure, the SLC 20 also has a structure including a gate insulating film 3, a floating gate 4, an interelectrode insulating film 5, and a control gate electrode 6.

The MLC 10 of the main memory region 80 and the SLC 20 of the buffer memory region 90 may be identical or different in structure. The p-region 2b provided in the surface of the semiconductor substrate 2 adjusts the threshold voltage of the SLC 20.

In writing data to the MLC 10, a writing voltage taking a plurality of potentials is applied to the control gate electrode 6. The different threshold voltages of the floating gate 4 corresponding to the respective potentials are associated with a plurality of bits to store data. On the other hand, in writing data to the SLC 20, the voltage applied to the control gate electrode 6 takes a single potential. On/off of the channel 22 below the floating gate 4 is associated with one bit.

As shown in FIG. 2B, a plurality of SLCs 20 are arranged in the second direction, which is the extending direction of the memory string in the buffer memory region 90. A source/drain region 17 as an n-type third semiconductor region is provided in the surface of the semiconductor substrate 2 between the SLCs 20 adjacent in the second direction parallel to the major surface 2a.

The source/drain region 15 and the source/drain region 17 can be formed by e.g. using the MLCs 10 and the SLCs 20 as a mask to perform selective ion implantation of n-type impurity into the surface of the semiconductor substrate 2, followed by heat treatment. The n-type impurity can be e.g. arsenic (As).

The p⁻-region 16 can be formed by using the MLCs 10 as a mask to perform ion implantation of p-type impurity into the surface of the source/drain region 15 (the surface of the semiconductor substrate 2 in the case of previously forming the p⁻-region 16), followed by heat treatment to diffuse the p-type impurity. Here, on the surface of the buffer memory region 90, for instance, a mask made of a photoresist is formed so as to avoid ion implantation of p-type impurity into the buffer memory region 90. The p-type impurity can be e.g. boron (B).

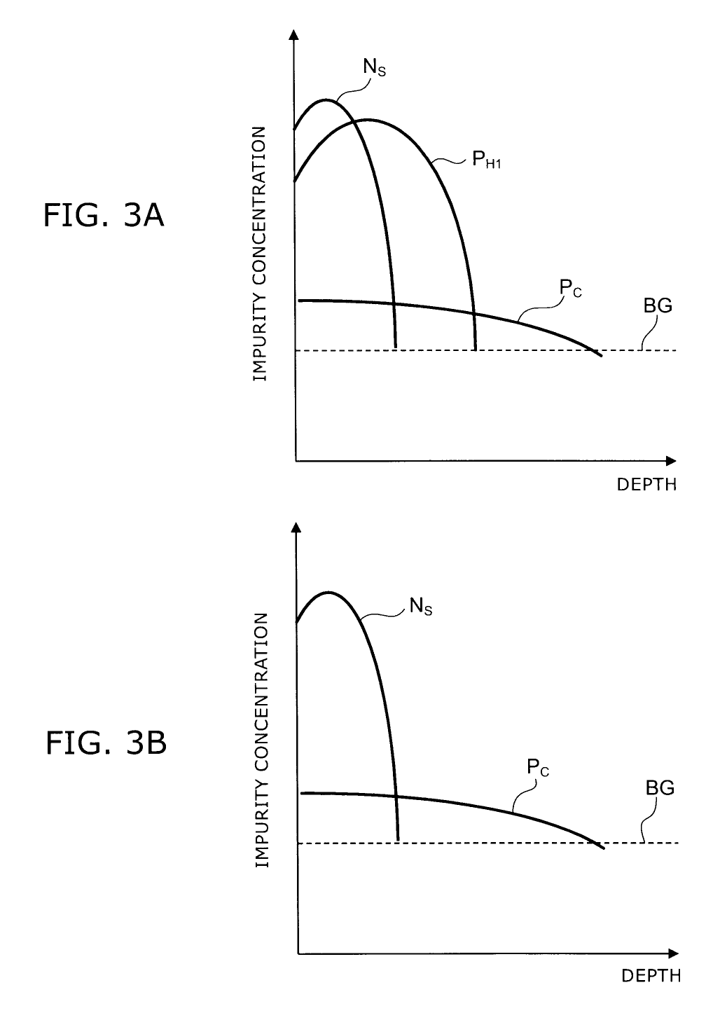

FIGS. 3A and 3B are schematic diagrams showing the distribution of impurity doped in the semiconductor memory device 100.

More specifically, FIG. 3A is a schematic diagram showing the profile of impurity distributed in the depth direction from the surface in the source/drain region 15. The dashed line shown in this figure represents the background level BG of p-type impurity doped in the semiconductor substrate 2. P_{C} represents the profile of p-type impurity implanted into the entire surface of the semiconductor substrate 2. That is, P_{C} represents the profile of p-type impurity in the p-region 2b formed to adjust the threshold voltage of the MLC 10 and the SLC 20. Ns represents the profile of n-type impurity implanted into the source/drain region 15. P_{H1} represents the profile of p-type impurity in the p⁻-region 16.

FIG. 3B shows the profile of impurity distributed in the depth direction from the surface in the source/drain region 17. This profile is different from the profile shown in FIG. 3A in that there is no doping with p-type impurity represented by P_{H1} in FIG. 3A.

Furthermore, the source/drain region 15 and the source/drain region 17 can be formed by simultaneous ion implantation of n-type impurity. In the source/drain region 15 and the source/drain region 17 formed by simultaneous ion implantation, the amount of second conductivity type impurity distributed in the depth direction of the semiconductor substrate 2 is equal and has the same profile N_{S}.

For instance, depending on the treatment in the manufacturing process, the amounts of n-type impurity included in the source/drain region 15 and the source/drain region 17 may be different. However, in most cases, the difference is small. In the sense that ion implantation is simultaneously performed, it can be said that the source/drain region 15 and the source/drain region 17 include the same amount of n-type impurity and have the same profile N_{S}.

In the following, the amount of impurity distributed in the depth direction of the semiconductor substrate 2 refers to the amount of impurity included per unit area of the substrate surface.

As shown in FIG. 3A, the profile N_{S} of n-type impurity forming the source/drain region 15 overlaps the profile P_{H1} of p-type impurity forming the p⁻-region 16. Hence, in the portion where N_{S} overlaps P_{H1}, P_{C}, and BG, the n-type impurity included in the source/drain region 15 is compensated by the p-type impurity included in P_{H1}, P_{C}, and BG.

On the other hand, in the case of the source/drain region 17 shown in FIG. 3B, the n-type impurity included in N_{S} is compensated by the p-type impurity included in P_{C} and BG.

That is, by the amount of the contribution of P_{H1}, the p-type impurity compensating the n-type impurity included in the source/drain region 15 is made more than the p-type impurity compensating the n-type impurity included in the source/drain region 17. Thus, the n-type carrier concentration of the source/drain region 15 is made lower than the n-type carrier concentration of the source/drain region 17 formed in the buffer memory region 90.

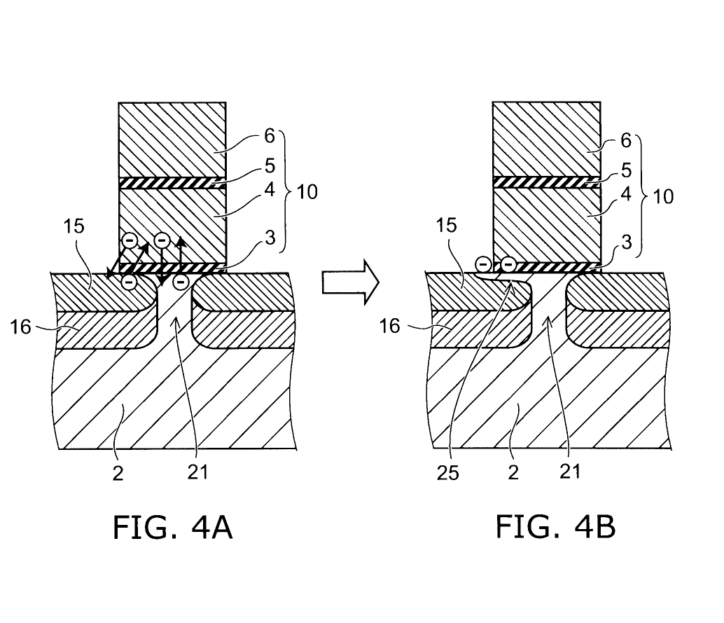

Next, degradation of the memory cell due to repeated writing and erasure in the semiconductor memory device 100 is described with reference to FIGS. 4A and 4B. FIGS. 4A and 4B are schematic sectional views showing the neighborhood of the MLC 10. More specifically, FIG. 4A conceptually shows the state before degradation of the MLC 10. FIG. 4B conceptually shows the state after the degradation.

As shown in FIG. 4A, the source/drain region 15 and the p⁻-region 16 are formed in the surface of the semiconductor substrate 2 on both sides of the MLC 10. The surface of the semiconductor substrate 2 immediately below the MLC 10 sandwiched between the source/drain regions 15 serves as a channel 21.

In the MLC 10, electrons are charged from the channel 21 through the gate insulating film 3 into the floating gate 4, or discharged from the floating gate 4 to the channel 21 by the voltage applied to the control gate electrode 6. Thus, writing and erasure of data are performed.

With repeated writing and erasure of data in the MLC 10, electrons are repeatedly charged and discharged between the channel 21 and the floating gate 4. Then, for instance, as shown in FIG. 4B, electrons are trapped in the gate insulating film 3 and the source/drain region 15. If the n-type carrier concentration of the source/drain region 15 is low, electrons trapped in the gate insulating film 3 and the source/drain region may form a depletion region 25 in the surface of the source/drain region 15.

In the state in which a depletion region 25 is formed in the surface of the source/drain region 15, for instance, even if a voltage higher than the threshold voltage is applied to the control gate electrode 6, it may be impossible to pass a current between the source/drain regions 15 provided on both sides of the MLC 10. That is, the inversion layer formed between the channel 21 and the gate insulating film 3 is interrupted by the depletion region 25 and fails to be connected to the source/drain region 15. Thus, the channel 21 of the MLC 10 may fail to be turned on and to work as a memory cell.

Such a degradation mode can be prevented by e.g. increasing the carrier concentration of the source/drain region 15 to avoid formation of the depletion region 25.

The semiconductor memory device 100 according to this embodiment is configured so as to suppress degradation of the SLCs 20 arranged in the buffer memory region 90 rather than the MLCs 10 arranged in the main memory region 80.

More specifically, the buffer memory region 90 is provided to alleviate the decrease of writing and reading speed of the main memory region 80 including the MLCs 10. The number of repetitions of writing and erasure in the buffer memory region 90 is larger than that in the main memory region 80 by nearly two orders of magnitude, for instance. Hence, the endurance characteristic of the semiconductor memory device 100 can be effectively improved by suppressing degradation of the SLCs 20 arranged in the buffer memory region 90.

Thus, as described above, the n-type carrier concentration of the source/drain region 17 formed in the buffer memory region 90 is made higher than that of the source/drain region 15 formed in the main memory region 80. This suppresses generation of the depletion layer 25 in the surface of the source/drain region 17 to suppress degradation of the SLCs 20. Thus, the endurance characteristic of the semiconductor memory device 100 can be improved.

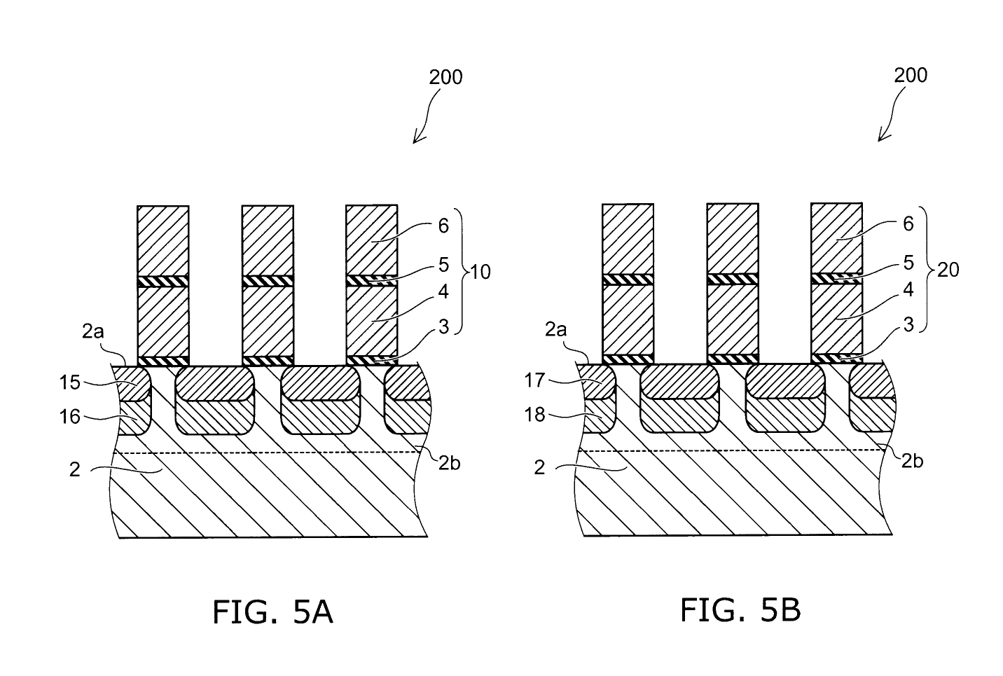

FIGS. 5A and 5B are schematic views showing the cross-sectional structure of a semiconductor memory device 200 according to a variation of this embodiment. More specifically, FIG. 5A shows the cross-sectional structure of the main memory region 80. FIG. 5B shows the cross-sectional structure of the buffer memory region 90.

In the semiconductor memory device 200, the main memory region 80 shown in FIG. 5A has the same structure as that of the semiconductor memory device 100 shown in FIG. 2A. On the other hand, the buffer memory region 90 shown in FIG. 5B is different in that a p⁻-region 18 (fourth semiconductor region) is provided below the source/drain region 17. The p⁻-region 18 includes p-type impurity selectively introduced from the surface of the source/drain region 17 and distributed in the depth direction of the semiconductor substrate 2. That is, the p⁻-region 18 is a so-called halo region.

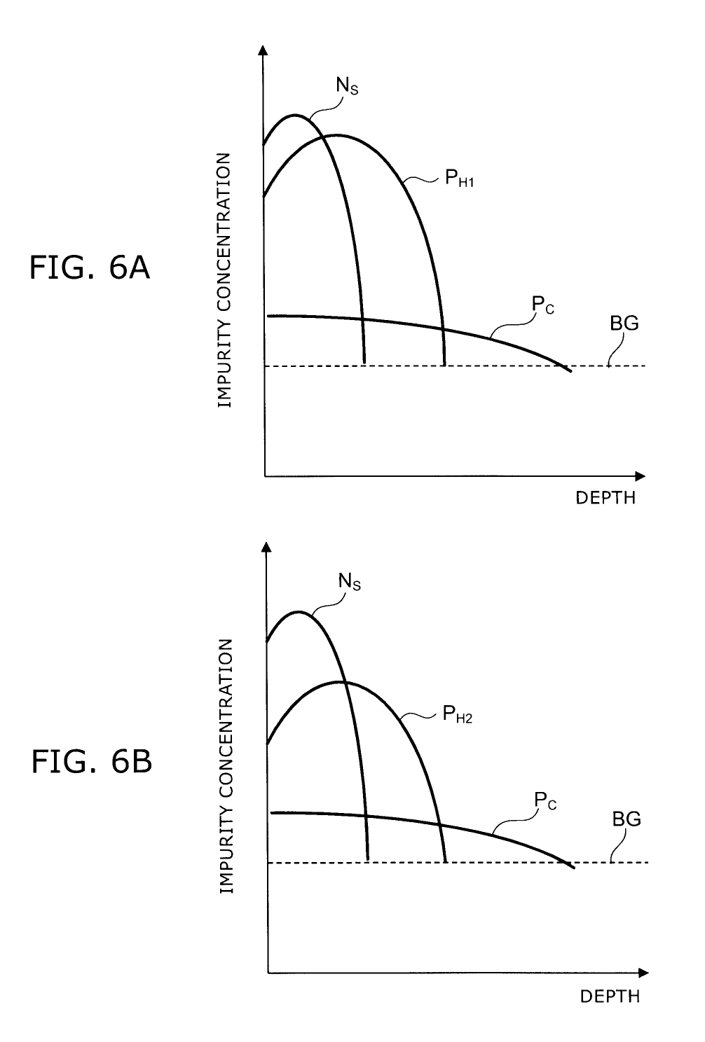

FIGS. 6A and 6B are schematic diagrams showing the distribution of impurity doped in the semiconductor memory device 200.

More specifically, FIG. 6A shows the profile of impurity distributed in the depth direction from the surface in the source/drain region 15. FIG. 6B shows the profile of impurity distributed in the depth direction from the surface in the source/drain region 17.

The impurity distribution shown in FIG. 6A is the same as the impurity distribution of the main memory region 80 in the semiconductor memory device 100 shown in FIG. 3A. On the other hand, FIG. 6B shows the profile P_{H2} of p-type impurity forming the p⁻-region 18. In this point, the impurity distribution shown in FIG. 6B is different from the impurity distribution of the buffer memory region 90 in the semiconductor memory device 100 shown in FIG. 3B.

As shown in FIG. 6B, the peak concentration of P_{H2} is lower than the peak concentration of P_{H1} shown in FIG. 6A. That is, the p-type impurity included in the p⁻-region 18 provided in the buffer memory region has a lower concentration than the p-type impurity of the p⁻-region 16 provided in the main memory region 80.

Hence, the amount of p-type impurity compensating the source/drain region 17 of the buffer memory region 90 is smaller than the amount of p-type impurity compensating the source/drain region 15 of the main memory region 80. Thus, the n-type carrier concentration of the source/drain region 17 is made higher than the n-type carrier concentration of the source/drain region 15. This can suppress generation of the depletion layer 25 (see FIG. 4B) in the source/drain region 17. As a result, degradation of the SLCs 20 arranged in the buffer memory region 90 is suppressed. Thus, the endurance characteristic of the semiconductor memory device 200 can be improved.

The p⁻-region 18 can be formed by using the SLCs 20 as an implantation mask to perform selective ion implantation of p-type impurity from the surface of the source/drain region 17 (the surface of the semiconductor substrate 2). The implantation amount (dose amount) of p-type impurity implanted into the p⁻-region 18 is made smaller than the implantation amount of p-type impurity implanted into the p⁻-region 16.

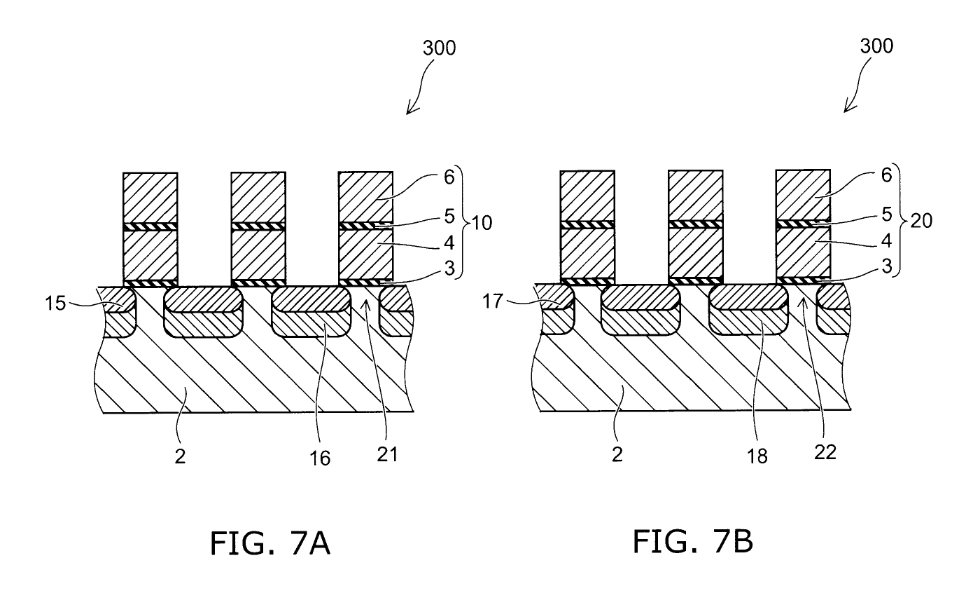

FIGS. 7A and 7B are schematic views showing the cross-sectional structure of a semiconductor memory device 300 according to an alternative variation of this embodiment. More specifically, FIG. 7A shows the cross-sectional structure of the main memory region 80. FIG. 7B shows the cross-sectional structure of the buffer memory region 90.

In the semiconductor memory device 300, the main memory region 80 includes MLCs 10. A source/drain region 15 and a p⁻-region 16 are provided between adjacent MLCs 10. Furthermore, the buffer memory region 90 includes SLCs 20. A source/drain region 17 and a p⁻-region 18 are provided between adjacent SLCs 20. In these points, the semiconductor memory device 300 is the same as the semiconductor memory device 200.

On the other hand, the surface of the semiconductor substrate 2 of the semiconductor memory device 300 does not include the p-region 2b (see FIGS. 5A and 5B) for adjusting the threshold voltage of the MLCs 10 of the main memory region 80 and the SLCs 20 of the buffer memory region 90. In this point, the semiconductor memory device 300 is different from the semiconductor memory device 200.

For instance, with the miniaturization of the semiconductor memory device 300, the channel length (the width in the Y direction in FIG. 2A) of the channels 21 and 22 is made shorter. Then, the threshold voltage of the MLC 10 and the SLC 20 is increased by diffusion in the Y direction of p-type impurity doped in the p⁻-region 16 and the p⁻-region 18. Thus, a sufficient threshold level can be ensured and eliminates the need of p-type impurity (P_{C}) for threshold adjustment.

Furthermore, the amount of p-type impurity included in the p⁻-region 18 provided in the buffer memory region 90 is made smaller than the amount of p-type impurity included in the p⁻-region 16. Thus, the n-type carrier concentration of the source/drain region 17 is made higher than the n-type carrier concentration of the source/drain region 15. This can suppress degradation of the SLCs 20 arranged in the buffer memory region 90

As an alternative structure, the p⁻-region 18 shown in FIG. 7B can be omitted. More specifically, the semiconductor memory device 100 shown in FIGS. 2A to 2C can also be configured so that the p-type impurity (P_{C}) for threshold adjustment is not doped in the surface of the semiconductor substrate 2. Then, the manufacturing process can be simplified by omitting the ion implantation step for forming the p⁻-region 18.

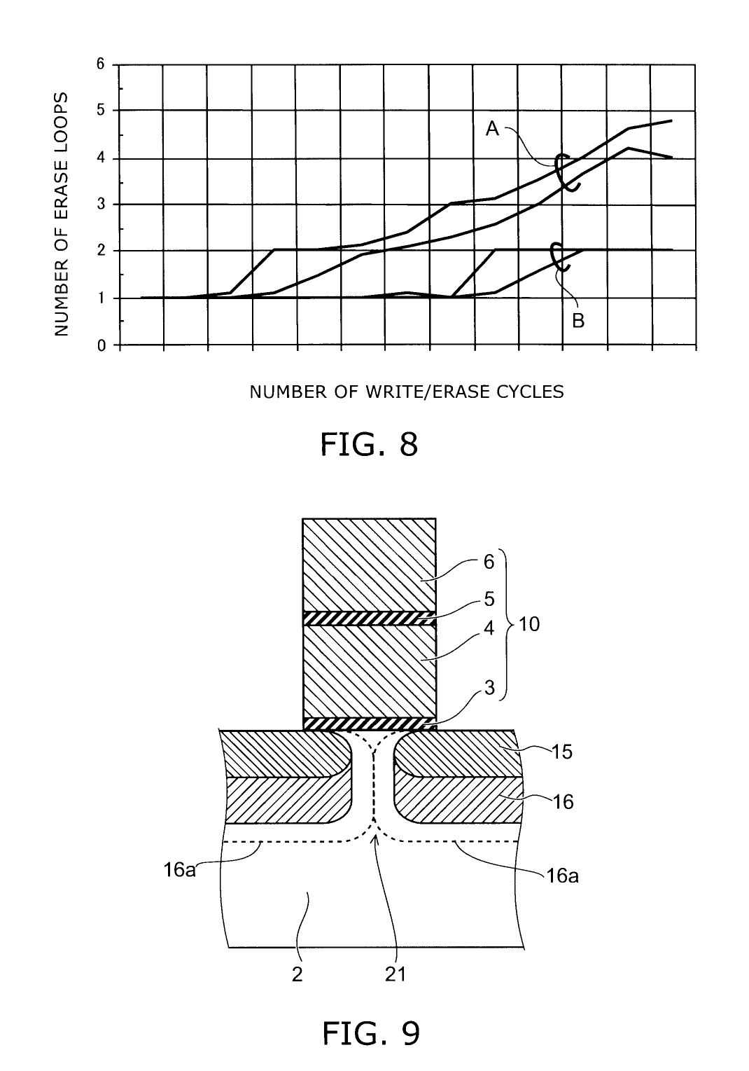

FIG. 8 is a graph showing the endurance for writing and erasure of the semiconductor memory device according to this embodiment. The horizontal axis represents the number of repetitions of writing and erasure, or so called write/erase cycles. The vertical axis represents the number of voltage cycles, or so-called erase loops, applied to the control gate electrode for data erasure.

Data A shown in FIG. 8 represents the characteristic of a semiconductor memory device in which the amount of p-type impurity included in the p⁻-region 16 provided in the main memory region 80 is made equal to the amount of p-type impurity included in the p⁻-region 18 provided in the buffer memory region 90.

On the other hand, data B represents the characteristic of the semiconductor memory device 300 in which the amount of p-type impurity included in the p⁻-region 18 is made smaller than the amount of p-type impurity included in the p⁻-region 16.

In data A, with the increase of the number of write/erase cycles, the number of erase loops increases. This indicates low endurance characteristic. In contrast, in data B, even with the increase of the number of write/erase cycles, the number of erase loops remains at most two. This indicates that the semiconductor memory device 300 has high endurance characteristic.

FIG. 9 is a schematic view showing the cross section of the MLC 10 of the semiconductor memory devices 200 and 300 according to this embodiment.

As described above, the main memory region 80 includes MLCs 10. A p⁻-region 16 is provided below the source/drain region 15. The amount of p-type impurity included in the p⁻-region 16 is larger than the amount of p-type impurity included in the p⁻-region 18 provided in the buffer memory region 90.

The p-type impurity doped in the p⁻-region 16 is e.g. boron (B). The p-type impurity can be easily diffused by heat treatment after ion implantation. Then, the p-type impurity doped in the p⁻-region 16 is diffused toward the channel 21 immediately below the MLC 10 as shown by the dashed line 16a in FIG. 9. This increases the concentration of p-type impurity of the channel 21.

Hence, the concentration of p-type impurity of the channel 21 in the main memory region 80 is made higher than the concentration of p-type impurity of the channel 22 in the buffer memory region 90. For instance, the amount of p-type impurity distributed from the surface of the semiconductor substrate 2 immediately below the MLC 10 to the depth of the concentration peak position of the p-type impurity included in the p⁻-region 16 is larger than the amount of p-type impurity distributed from the surface of the semiconductor substrate 2 immediately below the SLC 20 to the depth of the concentration peak position of the p-type impurity included in the p⁻-region 16.

This relation also applies to the semiconductor memory device 100 in which the buffer memory region 90 does not include the p⁻-region 18. The p-type impurity concentration of the channel 21 is made higher than the p-type impurity concentration of the channel 22.

FIGS. 10A and 10B are schematic diagrams showing the threshold distribution of the memory cells of the semiconductor memory devices 100-300 according to this embodiment. More specifically, FIG. 10A shows the threshold distribution of the MLCs 10. FIG. 10B shows the threshold distribution of the SLCs 20.

As shown in FIG. 10A, the MLC 10 is operated as a multi-level memory cell capable of storing two bits (“00”-“11”), for instance.

In contrast, as shown in FIG. 10B, the SLC 20 is operated as a binary memory cell for storing one bit (“0”, “1”).

As shown in FIGS. 10A and 10B, the center value of the highest threshold distribution in the MLCs 10 is set higher than the center value of the highest threshold distribution of the SLCs 20. To realize such a relation of threshold distributions, for instance, the threshold voltage in the MLC 10 is desirably higher than the threshold voltage in the SLC 20.

In the semiconductor memory devices 100-300 according to this embodiment, the concentration of p-type impurity of the channel 21 immediately below the MLC 10 can be made higher than the concentration of p-type impurity of the channel 22 immediately below the SLC 20. Thus, the threshold of the channel 21 can be made higher than the threshold of the channel 22.

While, as described above, the invention has been explained with reference to embodiments according to the invention, the invention is not limited to these embodiments. For example, an embodiment having the same technical concept as the invention such as design change and material change which can be performed by one skilled in the art on the basis of a technical level at the time of the application is also included in the technical range of the invention.

What is claimed is:

1. A semiconductor memory device comprising:
a plurality of multi-level memory cells provided on a major surface of a semiconductor substrate of a first conductivity type along a first direction parallel to the major surface;
a first semiconductor region of a second conductivity type selectively provided in the surface of the semiconductor substrate between the multi-level memory cells adjacent in the first direction;
a second semiconductor region provided deeper than the first semiconductor region from the major surface and including a first conductivity type impurity;
a plurality of binary memory cells provided on the major surface of the semiconductor substrate along a second direction parallel to the major surface; and
a third semiconductor region of the second conductivity type selectively provided in the surface of the semiconductor substrate between the binary memory cells adjacent in the second direction,
amount of the first conductivity type impurity compensating a second conductivity type impurity of the first semiconductor region being larger than amount of the first conductivity type impurity compensating the second conductivity type impurity of the third semiconductor region.

2. The device according to claim 1, further comprising:
a fourth semiconductor region provided deeper than the third semiconductor region from the major surface and including the first conductivity type impurity.

3. The device according to claim 2, wherein depth from the major surface of concentration peak of the second conductivity type impurity included in the third semiconductor region is shallower than depth from the major surface of concentration peak of the first conductivity type impurity included in the fourth semiconductor region.

4. The device according to claim 2, wherein peak concentration of the first conductivity type impurity included in the fourth semiconductor region is lower than peak concentration of the first conductivity type impurity included in the second semiconductor region.

5. The device according to claim 2, wherein concentration of the first conductivity type impurity included in the fourth semiconductor region is lower than that of the first conductivity type impurity included in the second semiconductor region.

6. The device according to claim 1, wherein concentration profile of the second conductivity type impurity in the first semiconductor region is identical to concentration profile of the second conductivity type impurity in the third semiconductor region.

7. The device according to claim 1, wherein concentration profile of the second conductivity type impurity in the first semiconductor region overlaps concentration profile of the first conductivity type impurity in the second semiconductor region, and concentration of second conductivity type carriers of the first semiconductor region is lower than concentration of second conductivity type carriers of the third semiconductor region.

8. The device according to claim 1, wherein amount of the first conductivity type impurity included in a range from the major surface to depth of concentration peak of the first conductivity type impurity included in the second semiconductor region immediately below the multi-level memory cell is larger than amount of the first conductivity type impurity included in a range from the major surface to depth of concentration peak of the first conductivity type impurity included in the second semiconductor region immediately below the binary memory cell.

9. The device according to claim 1, wherein concentration of the first conductivity type impurity immediately below the multi-level memory cell is higher than concentration of the first conductivity type impurity immediately below the binary memory cell.

10. The device according to claim 1, wherein center value of a highest threshold distribution in the multi-level memory cells is higher than center value of a highest threshold distribution of the binary memory cells.

11. The device according to claim 1, further comprising:
a main memory region including the multi-level memory cells; and
a buffer memory region including the binary memory cells.

12. The device according to claim 1, comprising:
a plurality of memory strings including the multi-level memory cells and extending in the first direction;
a plurality of memory strings including the binary memory cells and extending in the second direction; and
an STI electrically isolating adjacent ones of the memory strings from each other.

13. The device according to claim 1, wherein the first direction and the second direction are identical.

14. The device according to claim 1, wherein the multi-level memory cell and the binary memory cell include a gate insulating film, a floating gate, an interelectrode insulating film, and a control electrode provided sequentially on the semiconductor substrate.

15. The device according to claim 14, wherein
the multi-level memory cell is configured to associate a plurality of bits with a threshold voltage varied with a plurality of potentials applied to the control electrode, and
the binary memory cell is configured to associate one bit with on or off of a channel immediately therebelow.

16. The device according to claim 1, further comprising:
a fifth semiconductor region provided in the surface of the semiconductor substrate and including the first conductivity type impurity,
wherein the fifth semiconductor region adjusts thresholds of the multi-level memory cell and the binary memory cell.

17. A method for manufacturing a semiconductor memory device including a main memory region and a buffer memory region, the method comprising:
ion implanting a first conductivity type impurity into the main memory region using as a mask a multi-level memory cell provided in the main memory region; and
simultaneously ion implanting a second conductivity type impurity into the main memory region and the buffer memory region using as a mask the multi-level memory cell and a binary memory cell provided in the buffer memory region.

18. The method according to claim 17, further comprising:
ion implanting the first conductivity type impurity into the buffer memory region using the binary memory cell as a mask,
wherein dose amount of the first conductivity type impurity ion-implanted into the buffer memory region is smaller than dose amount of the first conductivity type impurity ion-implanted into the main memory region.

19. The method according to claim 17, further comprising:
ion implanting the first conductivity type impurity into entirety of the main memory region and the buffer memory region.

20. The method according to claim 17, wherein the first conductivity type impurity is boron, and the second conductivity type impurity is arsenic.
